(19) United States
(12) Patent Application Publication
(10) Pub. No.: US 2025/0214522 A1
(43) Pub. Date: Jul. 3, 2025

(54) WIRING HARNESS

(71) Applicant: SUMITOMO WIRING SYSTEMS, LTD., Mie (JP)

(72) Inventor: Hiroshi UENO, Mie (JP)

(21) Appl. No.: 18/875,171

(22) PCT Filed: Jun. 8, 2023
(86) PCT No.: PCT/JP2023/021339

§ 371 Date: Dec. 16, 2024

(30) Foreign Application Priority Data
Jun. 21, 2022 (JP) 2022-099594

(51) Int. Cl. B60R 16/027; B60R 16/02; H02G 3/04

(52) U.S. Cl. CPC B60R 16/027; B60R 16/0222; H02G 3/0468

(57) ABSTRACT

A wiring harness according to one aspect of the present disclosure includes a grommet (20) and a wire member (30) passed through the grommet (20). The grommet (20) holds the wire member (30) such that a twist angle (θ) of the wire member (30) when the opening/closing body is at a middle position between a fully open position and a fully closed position is 0° and the twist angle (θ) when the opening/closing body is at the fully closed position is a negative value if the twist angle (θ) when the opening/closing body is at the fully open position is a positive value.

### TECHNICAL FIELD

The present disclosure relates to a wiring harness.

### BACKGROUND

A vehicle wiring harness described in Patent Document 1 is, for example, provided with a wire member routed between a vehicle body side and an opening/closing body side such as a door and a grommet, through which the wire member is passed. The grommet is arranged between the vehicle body and the opening/closing body.

### PRIOR ART DOCUMENT

### Patent Document

Patent Document 1: JP 2012-111258 A

### SUMMARY OF THE INVENTION

### Problems to be Solved

In the wiring harness as described above, the wire member may be twisted as the opening/closing body is opened and closed.

The present disclosure aims to provide a wiring harness capable of suppressing the damage of a wire member by twist caused according to the opening and closing of an opening/closing body.

### Means to Solve the Problem

The present disclosure is directed to a wiring harness to be installed in an installation target including a fixed portion and an opening/closing body to be opened and closed with respect to the fixed portion between a fully open position and a fully closed position, the wiring harness being provided with a grommet to be arranged between the fixed portion and the opening/closing body and a wire member passed through the grommet, the grommet having a fixed-side end part to be fixed to the fixed portion and a movable-side end part to be fixed to the opening/closing body, the wire member being routed between the fixed portion and the opening/closing body while being passed through inside of the grommet, and the grommet holding the wire member such that a twist angle of the wire member when the opening/closing body is at a middle position between the fully open position and the fully closed position is 0° and the twist angle when the opening/closing body is at the fully closed position is a negative value if the twist angle when the opening/closing body is at the fully open position is a positive value.

### Effect of the Invention

A wiring harness of the present disclosure exhibits an effect of being capable of suppressing the damage of a wire member by twist caused according to the opening and closing of an opening/closing body.

### BRIEF DESCRIPTION OF THE DRAWINGS

FIG. 1 is a schematic configuration diagram showing an installation target installed with a wiring harness.

FIG. 2 is a plan view of the wiring harness of an embodiment.

FIG. 3 is a section along 3-3 in FIG. 2.

FIG. 4 is a schematic perspective view showing a movement of the wiring harness as an opening/closing body is opened and closed.

FIG. 5 is a diagram showing the twist of a wire member as the opening/closing body is opened and closed.

### DETAILED DESCRIPTION TO EXECUTE THE INVENTION

### Description of Embodiments of Present Disclosure

First, embodiments of the present disclosure are listed and described.

[1] The wiring harness of the present disclosure is to be installed in an installation target including a fixed portion and an opening/closing body to be opened and closed with respect to the fixed portion between a fully open position and a fully closed position, and provided with a grommet to be arranged between the fixed portion and the opening/closing body and a wire member passed through the grommet, the grommet having a fixed-side end part to be fixed to the fixed portion and a movable-side end part to be fixed to the opening/closing body, the wire member being routed between the fixed portion and the opening/closing body while being passed through inside of the grommet, and the grommet holding the wire member such that a twist angle of the wire member when the opening/closing body is at a middle position between the fully open position and the fully closed position is 0° and the twist angle when the opening/closing body is at the fully closed position is a negative value if the twist angle when the opening/closing body is at the fully open position is a positive value.

According to this configuration, the wire member is in an untwisted neutral state when the opening/closing body is at the middle position. The wire member can be configured to be twisted in opposite directions at the fully open position and the fully closed position. Therefore, a twist amount of the wire member according to the opening and closing of the opening/closing body can be suppressed to be small as compared to the case where the wire member is set to be in a neutral state when the opening/closing body is at the fully open position or the fully closed position. As a result, it is possible to suppress the damage of the wire member by twist caused according to the opening and closing of the opening/closing body.

[2] In [1] described above, an absolute value of the twist angle when the opening/closing body is at the fully open position and an absolute value of the twist angle when the opening/closing body is at the fully closed position may be equal.

According to this configuration, the twist amount of the wire member at the fully open position and that at the fully closed position can be equal. Therefore, the twist amount of the wire member according to the opening and closing of the opening/closing body can be suppressed to a minimum level.

[3] In [1] or [2] described above, the middle position may be a center position between the fully open position and the fully closed position.

According to this configuration, the twist amount of the wire member at the fully open position and that at the fully closed position can be equal. Therefore, the twist amount of the wire member according to the opening and closing of the opening/closing body can be suppressed to a minimum level.

[4] In any one of [1] to [3] described above, if a straight line connecting a center of the movable-side end part and a center of the fixed-side end part when the opening/closing body is at the fully open position is a first virtual straight line, a straight line connecting the center of the movable-side end part and the center of the fixed-side end part when the opening/closing body is at the fully closed position is a second virtual straight line and a straight line connecting the center of the movable-side end part and the center of the fixed-side end part when the opening/closing body is at the middle position is a third virtual straight line, the third virtual straight line may be set at a position bisecting an angle between the first and second virtual straight lines.

According to this configuration, the twist amount of the wire member at the fully open position and that at the fully closed position can be equal. Therefore, the twist amount of the wire member according to the opening and closing of the opening/closing body can be suppressed to a minimum level.

[5] In any one of [1] to [4] described above, the wire member may include a braided member.

According to this configuration, the wire member includes the braided member easily damaged by twist. Thus, a damage suppression effect by suppressing the twist amount of the wire member to be small can be significantly obtained.

### Details of Embodiment of Present Disclosure

A specific example of a wiring harness of the present disclosure is described below with reference to the drawings. For the convenience of description, some components may be shown in an exaggerated or simplified manner in each drawing. Further, a dimension ratio of each part may be different in each drawing. Note that a term “tubular” used in the description of this specification indicates not only a shape formed by a peripheral wall continuous over an entire periphery in a circumferential direction, but also a shape formed by combining a plurality of components and a shape having a cut or the like in a circumferential part such as a C shape. Further, the “tubular” shapes include circular shapes, elliptical shapes and polygonal shapes with angular or rounded corners.

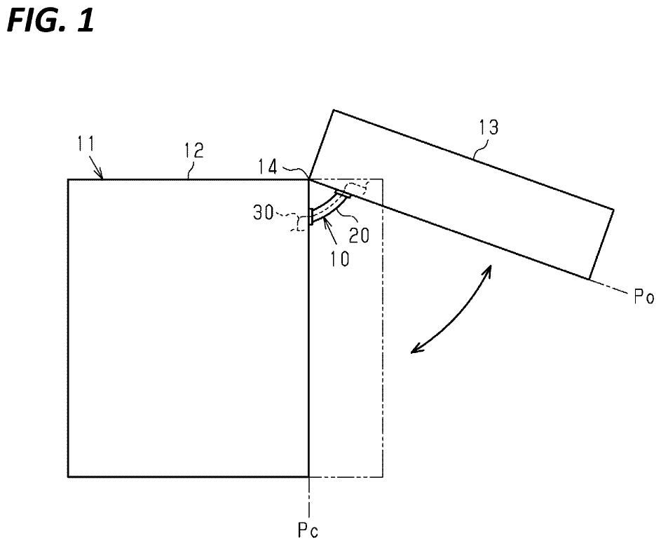

As shown in FIG. 1, a wiring harness 10 of this embodiment is installed in an installation target 11. The installation target 11 is provided with a fixed portion 12 and an opening/closing body 13 supported on the fixed portion 12. The opening/closing body 13 is configured to be openable and closable between a fully open position Po and a fully closed position Pc with respect to the fixed portion 12. The installation target 11 is, for example, a vehicle. The fixed portion 12 is, for example, a vehicle body. The opening/closing body 13 is, for example, a back door, a side door, a slide door, an opening/closing body of a sunroof device, a side mirror, a rearview mirror, or the like.

The opening/closing body 13 is, for example, coupled to the fixed portion 12 via a hinge shaft 14. The opening/closing body 13 is configured to be rotatable between the fully open position Po and the fully closed position Pc with the hinge shaft 14 as a rotary shaft.

### (Configuration of Wiring Harness 10)

The wiring harness 10 is provided with a grommet 20 and a wire member 30. The grommet 20 is made of a flexible material. Rubber, elastomer or the like can be, for example, used as the material of the grommet 20.

The grommet 20 is provided between the fixed portion 12 and the opening/closing body 13. Further, the grommet 20 is, for example, provided near the hinge shaft 14. The grommet 20 has a tubular shape as a whole. The wire member 30 is passed through the grommet 20. The wire member 30 is routed between the fixed portion 12 and the opening/closing body 13 while being passed through the inside of the grommet 20. One end part of the wire member 30 is connected to an unillustrated device provided in the opening/closing body 13.

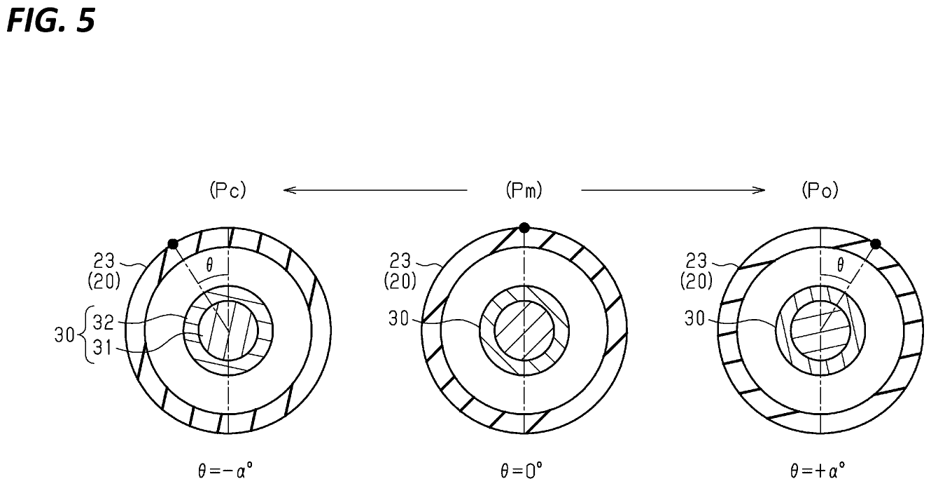

As shown in FIG. 5, the wire member 30 is, for example, an LVDS (Low Voltage Differential Signaling) cable including a wire 31 and a braided member 32 covering the outer periphery of the wire 31. The wire 31 is one wire including a core wire and an insulation coating or a bundle of a plurality of wires. The braided member 32 is, for example, formed by braiding a plurality of metal strands. The braided member 32 electrically shields the wire 31.

### (Configuration of Grommet 20)

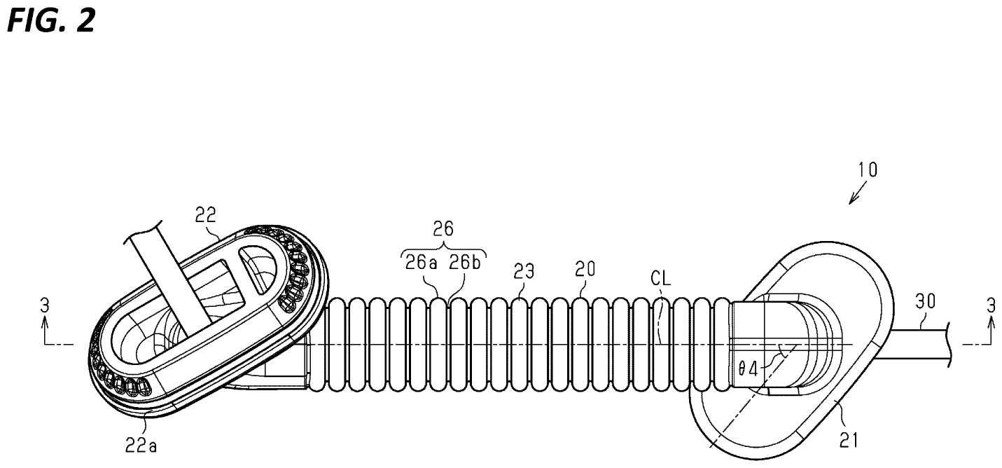

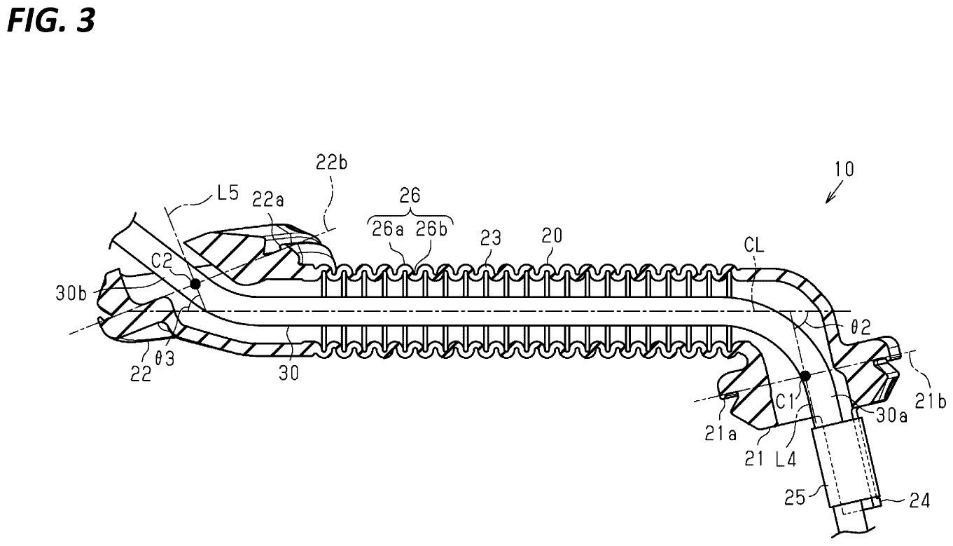

As shown in FIGS. 2 and 3, the grommet 20 includes a fixed-side end part 21, a movable-side end part 22 and a middle part 23. The fixed-side end part 21 is provided in one end in a longitudinal direction of the grommet 20. The movable-side end part 22 is provided in the other end part in the longitudinal direction of the grommet 20. The middle part 23 is a part connecting the fixed-side end part 21 and the movable-side end part 22. For example, each of the fixed-side end part 21 and the movable-side end part 22 radially extends like a flange with respect to the middle part 23. The wire 30 is passed through the fixed-side end part 21, the middle part 23 and the movable-side end part 22 in the grommet 20.

As shown in FIG. 3, the grommet 20 includes a fixing piece 24, to which the wire member 30 is fixed. The fixing piece 24 is, for example, provided on the fixed-side end part 21. The wire member 30 is, for example, fixed to the fixing piece 24 by an adhesive tape 25.

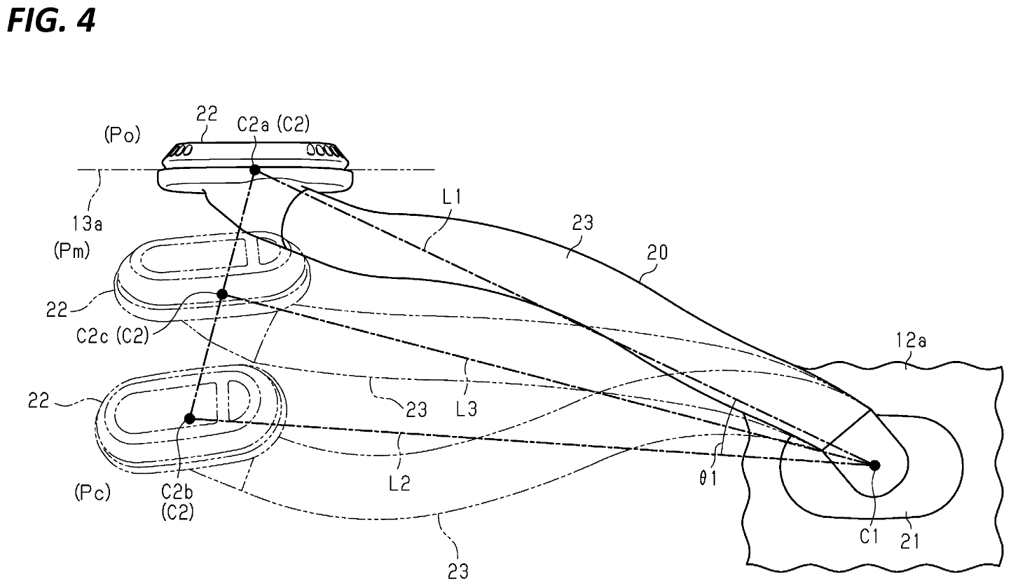

The middle part 23 includes a bellows portion 26 at least in one part in the longitudinal direction. The bellows portion 26 is in the form of bellows having small and large diameters repeated in the longitudinal direction. That is, the bellows portion 26 is structured such that large-diameter portions 26a and small-diameter portions 26b are alternately connected along the longitudinal direction. Note that the detailed shape of the bellows portion 26 is not shown in FIG. 4 for the convenience of description.

As shown in FIG. 4, the fixed-side end part 21 is fixed to a mounting surface 12a of the fixed portion 12. The movable-side end part 22 is fixed to a mounting surface 13a of the opening/closing body 13.

As shown in FIG. 3, the fixed-side end part 21 includes a lip portion 21a to be held in close contact with the mounting surface 12a. The lip portion 21a has an annular shape. The lip portion 21a is held in close contact with the mounting surface 12a at a position surrounding an unillustrated through hole formed in the mounting surface 12a. In this way, the lip portion 21a seals this through hole. Note that a later-described center C1 of the fixed-side end part 21 is aligned with a center of the annular lip portion 21a. The wire member 30 enters the fixed portion 12 through the through hole of the mounting surface 12a.

The movable-side end part 22 includes a lip portion 22a to be held in close contact with the mounting surface 13a. The lip portion 22a has an annular shape. The lip portion 22a is held in close contact with the mounting surface 13a at a position surrounding an unillustrated through hole formed in the mounting surface 13a. In this way, the lip portion 22a seals this through hole. Note that a later-described center C2 of the movable-side end part 22 is aligned with a center of the annular lip portion 22a. The wire member 30 enters the opening/closing body 13 through the through hole of the mounting surface 13a.

(Concerning Twist according to Opening and Closing of Opening/Closing Body 13)

As shown in FIG. 4, the mounting surface 13a of the opening/closing body 13 and the movable-side end part 22 of the grommet 20 are displaced as the opening/closing body 13 is opened and closed. The movable-side end part 22 is displaced with respect to the fixed-side end part 21 not displaced when the opening/closing body 13 is opened and closed, whereby the middle part 23 of the grommet 20 and the wire member 30 in the grommet 20 are twisted. The “twist” of the grommet 20 and the wire member 30 is deformation when the grommet 20 and the wire member 30 are rotated in a plane perpendicular to the longitudinal direction.

As shown in FIG. 3, a part of the wire member 30 located inside the fixed-side end part 21 is a first part 30a and a part thereof located inside the movable-side end part 22 is a second part 30b. A twist angle θ of the wire member 30 in the following description indicates an angle of the twist of the second part 30b with respect to the first part 30a.

As shown in FIG. 5, when the opening/closing body 13 is at a middle position Pm between the fully open position Po and the fully closed position Pc, the twist angle θ of the wire member 30 is 0°. That is, the wire member 30 is not twisted at the middle position Pm. The twist angle θ is a positive value when the opening/closing body 13 is at the fully open position Po, and the twist angle θ is a negative value when the opening/closing body 13 is at the fully closed position Pc. That is, the second part 30b of the wire member 30 is twisted in opposite directions at the fully open position Po and the fully closed position Pc.

As shown in FIG. 4, the center C2 of the movable-side end part 22 when the opening/closing body 13 is at the fully open position Po is an open-time center C2a. Further, the center C2 of the movable-side end part 22 when the opening/closing body 13 is at the fully closed position Pc is a close-time center C2b. Further, the center C2 of the movable-side end part 22 when the opening/closing body 13 is at the middle position Pm is a middle-time center C2c. Further, a straight line connecting the center C1 of the fixed-side end part 21 and the open-time center C2a of the movable-side end part 22 is a first virtual straight line L1. A straight line connecting the center C1 of the fixed-side end part 21 and the close-time center C2b of the movable-side end part 22 is a second virtual straight line L2. The first and second virtual straight lines L1, L2 are set to have an equal length. That is, a triangle having the center C1, the open-time center C2a and the close-time center C2b of the fixed-side end part 21 as vertices is an isosceles triangle.

Here, the middle position Pm of the opening/closing body 13 is a center position between the fully open position Po and the fully closed position Pc. That is, in the opening/closing body 13, a movement amount from the middle position Pm to the fully open position Po and that from the middle position Pm to the fully closed position Pc are equal. Accordingly, if a straight line connecting the center C1 of the fixed-side end part 21 and the middle-time center C2c of the movable-side end part 22 is a third virtual straight line L3, the third virtual straight line L3 is a straight line bisecting an angle θ1 between the first and second virtual straight lines L1, L2. In this way, an absolute value |α| of the twist angle θ when the opening/closing body 13 is at the fully open position Po and an absolute value |α| of the twist angle θ when the opening/closing body 13 is at the fully closed position Pc are equal. That is, the wire member 30 is twisted by the same amount at the fully open position Po and the fully closed position Pc.

As shown in FIG. 3, a center axis L4 of the fixed-side end part 21 in the grommet 20 is orthogonal to a seat surface 21b of the fixed-side end part 21 and passes through the center C1 of the fixed-side end part 21. An angle between an axis CL along the longitudinal direction of the middle part 23 and the center axis L4 is a first elevation/depression angle θ2. Further, a center axis L5 of the movable-side end part 22 is orthogonal to a seat surface 22b of the movable-side end part 22 and passes through the center C2 of the movable-side end part 22. An angle between the axis CL of the middle part 23 and the center axis L5 is a second elevation/depression angle θ3.

Further, a rotation angle θ4 of the fixed-side end part 21 shown in FIG. 2 is an angle of the fixed-side end part 21 with respect to the axis CL. The rotation angle θ4 is an angle in a rotation direction about the center axis L4 of the fixed-side end part 21. Further, the movable-side end part 22 also has a rotation angle similar to the rotation angle θ4.

The first elevation/depression angle θ2 of the fixed-side end part 21, the rotation angle θ4 of the fixed-side end part 21, the second elevation/depression angle θ3 of the movable-side end part 22 and the rotation angle of the movable-side end part 22 are so set that the middle part 23 does not interfere with the fixed portion 12 and the opening/closing body 13 in an assembled state with the installation target 11. Further, the first elevation/depression angle θ2 of the fixed-side end part 21, the rotation angle θ4 of the fixed-side end part 21, the second elevation/depression angle θ3 of the movable-side end part 22 and the rotation angle of the movable-side end part 22 are so set that the middle part 23 interferes with the wire member 30 and stress is not concentrated partially on the wire member 30 when the opening/closing body 13 is opened and closed.

Effects of this embodiment are described.

(1) The grommet 20 holds the wire member 30 such that the twist angle θ is 0° when the opening/closing body 13 is at the middle position Pm between the fully open position Po and the fully closed position Pc. According to this configuration, the wire member 30 is in an untwisted neutral state when the opening/closing body 13 is at the middle position Pm. The wire member 30 can be configured to be twisted in the opposite directions at the fully open position Po and the fully closed position Pc. Therefore, a twist amount of the wire member 30 according to the opening and closing of the opening/closing body 13 can be suppressed to be small as compared to the case where the wire member 30 is set to be in the neutral state when the opening/closing body 13 is at the fully open position Po or the fully closed position Pc. As a result, the damage of the wire member 30 by twist according to the opening and closing of the opening/closing body 13 can be suppressed.

(2) The absolute value of the twist angle θ when the opening/closing body 13 is at the fully open position Po and that of the twist angle θ when the opening/closing body 13 is at the fully closed position Pc are equal. According to this configuration, the twist amount of the wire member 30 at the fully open position Po and that at the fully closed position Pc can be set to be equal. Therefore, the twist amount of the wire member 30 according to the opening and closing of the opening/closing body 13 can be suppressed to a minimum level.

(3) The middle position Pm is a center position between the fully open position Po and the fully closed position Pc. According to this configuration, the twist amount of the wire member 30 at the fully open position Po and that at the fully closed position Pc can be set to be equal. Therefore, the twist amount of the wire member 30 according to the opening and closing of the opening/closing body 13 can be suppressed to a minimum level.

(4) The straight line connecting the center C2 of the movable-side end part 22 and the center C1 of the fixed-side end part 21 when the opening/closing body 13 is at the fully open position Po is the first virtual straight line L1. Further, the straight line connecting the center C2 of the movable-side end part 22 and the center C1 of the fixed-side end part 21 when the opening/closing body 13 is at the fully closed position Pc is the second virtual straight line L2. Further, the straight line connecting the center C2 of the movable-side end part 22 and the center C1 of the fixed-side end part 21 when the opening/closing body 13 is at the middle position Pm is the third virtual straight line L3. The third virtual straight line L3 is set at a position bisecting the angle θ1 between the first and second virtual straight lines L1, L2. According to this configuration, the twist amount of the wire member 30 at the fully open position Po and that at the fully closed position Pc can be set to be equal. Therefore, the twist amount of the wire member 30 according to the opening and closing of the opening/closing body 13 can be suppressed to a minimum level.

(5) The wire member 30 includes the braided member 32 easily damaged by twist. Thus, a damage suppression effect by suppressing the twist amount of the wire member 30 to be small can be significantly obtained. Further, the wire member 30 includes a braided member included in the LVDS cable of the wire 31. Since this braided member is easily damaged by twist similarly to the braided member 32, the damage suppression effect can be more significantly obtained.

### (Modifications)

This embodiment can be modified and carried out as follows. This embodiment and the following modifications can be carried out in combination without technically contradicting each other.
The third virtual straight line L3 may be set a position not bisecting the angle θ1 between the first and second virtual straight lines L1, L2.
The middle position Pm may not be the center position between the fully open position Po and the fully closed position Pc.
The absolute value of the twist angle θ when the opening/closing body 13 is at the fully open position Po and that of the twist angle θ when the opening/closing body 13 is at the fully closed position Pc may not be equal. Note that the twist amount of the wire member 30 according to the opening and closing of the opening/closing body 13 decreases as a difference between the absolute value of the twist angle θ when the opening/closing body 13 is at the fully open position Po and that of the twist angle θ when the opening/closing body 13 is at the fully closed position Pc decreases.
The first and second virtual straight lines L1, L2 may be set to have mutually different lengths. Notte that bending amounts of the middle part 23 and the wire member 30 according to the opening and closing of the opening/closing body 13 decreases as a difference between the length of the first virtual straight line L1 and that of the second virtual straight line L2 decreases.
The wire member 30 may be fixed to the fixing piece 24, for example, by a zip tie.
The fixing piece 24 may be provided only on the movable-side end part 22 or on each of the fixed-side end part 21 and the movable-side end part 22.
The wire member 30 may be configured to include a plurality of wires 31 or may be configured to include the wire 31 and one or more different wires.
The wire member 30 is not limited to the LVDS cable including the wire 31 and the braided member 32. For example, the core wire of the wire 31 may be constituted by a braided member formed by braiding a plurality of metal strands. In this case, the core wire of the wire 31 is constituted by the braided member easily damaged by twist, wherefore the damage suppression effect by suppressing the twist amount of the wire member 30 to be small can be significantly obtained.
As shown in FIGS. 1 and 4, the hinge shaft 14 (rotary shaft) may be located between the movable-side end part 22 of the grommet 20 and the fixed-side end part 21 of the grommet 20 at the fully open position Po and may be formed to extend in the same direction as an extension direction of the mounting surface 12a of the fixed portion 12.
The movable-side end part 22 of the grommet 20 may be provided on an end side in an axial direction of the hinge shaft 14 rather than on the fixed-side end part 21 of the grommet 20.
The open-time center C2a, the close-time center C2b and the middle-time center C2c of the movable-side end part 22 of the grommet 20 may be aligned with a center of the through hole, which is formed in the mounting surface 13a of the opening/closing body 13 and in which the movable-side end part 22 is fixed, and the center C1 of the fixed-side end part 21 of the grommet 20 may be aligned with a center of the through hole, which is formed in the mounting surface 12a of the fixed portion 12 and in which the fixed-side end part 21 is fixed. The open-time center C2a, the close-time center C2b and the middle-time center C2c may be located on mutually different planes.
As shown in FIGS. 3 and 4, the first part 30a of the wire member 30 may be fixed to the fixed-side end part 21 of the grommet 20, and the second part 30b of the wire member 30 may be twisted about the hinge shaft 14 with respect to the first part 30a of the wire member 30 together with the movable-side end part 22 of the grommet 20 when the opening/closing body 13 is at the fully open position Po or the fully closed position Pc.

[Addendum 1] The wiring harness 10 according to several embodiments of the present disclosure may be provided with the long tubular grommet 20 to be resiliently connected to the opening/closing body 13 movable to the fully open position Po and the fully closed position Pc and the wire member 30 passed through the long tubular grommet 20. For example, as shown in FIG. 5,
the wire member 30 held in the grommet 20 may be in a first twisted state when the opening/closing body 13 is at the fully closed position Pc,
the wire member 30 held in the grommet 20 may be in a second twisted state different from the first twisted state when the opening/closing body 13 is at the fully open position Po, and
the wire member 30 held in the grommet 20 may be in an untwisted state different from the first and second twisted states when the opening/closing body 13 is at the middle position Pm.

[Addendum 2] In several embodiments of the present disclosure, the wire member 30 may include an LVDS cable including a metal braided member.

[Addendum 3] For example, as shown in FIG. 3, in several embodiments of the present disclosure, the wire member 30 held in the grommet 20 may have a first length position, which can be the first part 30a corresponding to the fixed-side end part 21 of the grommet, and a second length position, which can be the second part 30b corresponding to the movable-side end part 22 of the grommet 20.

[Addendum 4] For example, as shown in FIG. 5, in several embodiments of the present disclosure, in a cross-sectional view of the wire member 30, the second length position of the wire member 30 may be twisted in one of a clockwise direction (CW) and a counterclockwise direction (CCW) with respect to the first length position of the wire member 30 when the opening/closing body 13 is at the fully closed position Pc and the wire member 30 held in the grommet 20 is in the first twisted state, the second length position of the wire member 30 may be twisted in the other of the clockwise direction and the counterclockwise direction with respect to the first length position of the wire member 30 when the opening/closing body 13 is at the fully open position Po and the wire member 30 held in the grommet 20 is in the second twisted state, and the second length position of the wire member 30 may be twisted neither in the clockwise direction nor in the counterclockwise direction with respect to the first length position of the wire member 30 when the opening/closing body 13 is at the middle position Pm and the wire member 30 held in the grommet 20 is in the untwisted state.

[Addendum 5] For example, as shown in FIG. 5, in several embodiments of the present disclosure, in a cross-sectional view of the wire member 30, the second length position of the wire member 30 may be twisted at a first twist angle (−α°) in one of the clockwise direction and the counterclockwise direction with respect to the first length position of the wire member 30 when the opening/closing body 13 is at the fully closed position Pc and the wire member 30 held in the grommet 20 is in the first twisted state, and the second length position of the wire member 30 may be twisted at a second twist angle (+α°) in the other of the clockwise direction and the counterclockwise direction with respect to the first length position of the wire member 30 when the opening/closing body 13 is at the fully open position Po and the wire member 30 held in the grommet 20 is in the second twisted state.

[Addendum 6] For example, as shown in FIG. 5, in several embodiments of the present disclosure, an absolute value of the first twist angle (−α°) and that of the second twist angle (+α°) may be equal.

The embodiment and the modifications disclosed this time should be considered illustrative in all aspects, rather than restrictive. That is, the scope of the present invention is represented by claims and intended to include all changes in the scope of claims and in the meaning and scope of equivalents.

### LIST OF REFERENCE NUMERALS

10 wiring harness
11 installation target
12 fixed portion
12a mounting surface
13 opening/closing body
13a mounting surface
14 hinge shaft
20 grommet
21 fixed-side end part
21a lip portion
21b seat surface
22 movable-side end part
22a lip portion
22b seat surface
23 middle part
24 fixing piece
25 adhesive tape
26 bellows portion
26a large-diameter portion
26b small-diameter portion
30 wire member
30a first part
30b second part
31 wire
32 braided member
θ twist angle
θ1 angle
θ2 first elevation/depression angle
θ3 second elevation/depression angle
θ4 rotation angle
C1 center of fixed-side end part
C2 center of movable-side end part
C2a open-time center
C2b close-time center
C2c middle-time center
CL axis
L1 first virtual straight line
L2 second virtual straight line
L3 third virtual straight line
L4 center axis
L5 center axis
Pc fully closed position
Pm middle position
Po fully open position

1. A wiring harness to be installed in an installation target including a fixed portion, the fixed portion being a vehicle body, and an opening/closing body to be opened and closed with respect to the fixed portion between a fully open position and a fully closed position, comprising:
a grommet to be arranged between the fixed portion and the opening/closing body; and
a wire member passed through the grommet,
the wire member including an LVDS cable having a metal braided member,
the grommet having a fixed-side end part to be fixed to the fixed portion and a movable-side end part to be fixed to the opening/closing body,
the wire member being routed between the fixed portion and the opening/closing body while being passed through inside of the grommet, and
the grommet holding the wire member such that a twist angle of the wire member when the opening/closing body is at a middle position between the fully open position and the fully closed position is 0° and the twist angle when the opening/closing body is at the fully closed position is a negative value if the twist angle when the opening/closing body is at the fully open position is a positive value.

2. The wiring harness of claim 1, wherein an absolute value of the twist angle when the opening/closing body is at the fully open position and an absolute value of the twist angle when the opening/closing body is at the fully closed position are equal.

3. The wiring harness of claim 1, wherein the middle position is a center position between the fully open position and the fully closed position.

4. The wiring harness of claim 1, wherein, if a straight line connecting a center of the movable-side end part and a center of the fixed-side end part when the opening/closing body is at the fully open position is a first virtual straight line, a straight line connecting the center of the movable-side end part and the center of the fixed-side end part when the opening/closing body is at the fully closed position is a second virtual straight line and a straight line connecting the center of the movable-side end part and the center of the fixed-side end part when the opening/closing body is at the middle position is a third virtual straight line, the third virtual straight line is set at a position bisecting an angle between the first and second virtual straight lines.

5. The wiring harness of claim 1, wherein the opening/closing body is selected from a back door of a vehicle, a side door of the vehicle, a slide door of the vehicle, an opening/closing body of a sunroof device of the vehicle and combinations thereof.
